(19) United States
(12) Patent Application Publication
(10) Pub. No.: US 2025/0176431 A1
(43) Pub. Date: May 29, 2025

(54) METHOD FOR PRODUCING A DONOR SUBSTRATE FOR TRANSFERRING A PIEZOELECTRIC LAYER, AND METHOD FOR TRANSFERRING A PIEZOELECTRIC LAYER TO A CARRIER SUBSTRATE

(71) Applicant: Soitec, BERNIN (FR)

(72) Inventors: Marcel Broekaart, BERNIN (FR); Cédric Charles-Alfred, BERNIN (FR); Luciana Capello, BERNIN (FR); Morgane Logiou, BERNIN (FR); Thierry Barge, BERNIN (FR)

(21) Appl. No.: 18/729,023

(22) PCT Filed: Jan. 11, 2023
(86) PCT No.: PCT/EP2023/050567

§ 371 Date: Jul. 15, 2024

(30) Foreign Application Priority Data
Jan. 17, 2022 (FR) FR2200381

(51) Int. Cl. H10N 30/073

(52) U.S. Cl. CPC H10N 30/073

(57) ABSTRACT

A method of manufacturing a donor substrate for the transfer of a piezoelectric layer onto a support substrate comprises providing a handling substrate and a piezoelectric substrate. A surface activation treatment is carried out on the surface of the piezoelectric substrate to form an activated surface on the piezoelectric substrate. A polymer layer is deposited on the activated surface of the piezoelectric substrate or on the handling substrate. The piezoelectric substrate is then assembled on the handling substrate in such a way that the polymer layer is between the activated surface of the piezoelectric substrate and the handling substrate. The donor substrate may be used to transfer a layer of piezoelectric material from the donor substrate onto a support substrate.

### CROSS-REFERENCE TO RELATED APPLICATIONS

This application is a national phase entry under 35 U.S.C. § 371 of International Patent Application PCT/EP2023/050567, filed Jan. 11, 2023, designating the United States of America and published as International Patent Publication WO 2023/135179 A1 on Jul. 20, 2023, which claims the benefit under Article 8 of the Patent Cooperation Treaty of French Patent Application Serial No. FR2200381, filed Jan. 17, 2022.

### TECHNICAL FIELD

The present disclosure relates to a process for the manufacture of a donor substrate for the transfer of a piezoelectric layer and to a process for transfer of such a piezoelectric layer onto a support substrate.

### BACKGROUND

A piezoelectric-on-insulator (POI) substrate comprises a thin layer of piezoelectric material on a substrate. In order to manufacture such a POI substrate, the process used comprises the transfer of the thin piezoelectric layer onto a support substrate starting from a thick substrate of piezoelectric material.

For this, first a donor substrate is used in which a bulk substrate of piezoelectric material is assembled with a handling substrate by bonding using a polymer layer. Subsequently, the donor substrate is subjected to a stage of thinning the bulk piezoelectric substrate to form a thinner piezoelectric layer, before being assembled with the support substrate. Finally, the transfer of the piezoelectric layer onto the support substrate is carried out mechanically or thermally at the level of a fracturing zone created beforehand in the thinned piezoelectric layer. The donor substrate is introduced into the process in order to limit the negative impact of the difference in the thermal expansion coefficients between the piezoelectric material and the support substrate of the POI. This is because, in order to strengthen the bonding interface between the different substrates and for the transfer of the thin layer, heat treatments are carried out. An example of this type of process is described in WO 2019/186032 A1.

Thus, during the process for the manufacture of a POI substrate, the donor substrate undergoes several stages of heat and/or mechanical treatments and must exhibit good mechanical strength to the different treatments.

However, debonding at the level of the bonding interface between the piezoelectric material substrate and the polymer layer of the donor substrate can take place during the successive thermal and/or mechanical stages of the piezoelectric layer transfer process.

### BRIEF SUMMARY

One aim of the present disclosure is to overcome the abovementioned disadvantages and, in particular, to design a donor substrate for the transfer of a piezoelectric layer of a piezoelectric material substrate onto a support substrate, which exhibits a better mechanical strength for the piezoelectric layer transfer process.

The subject matter of the present disclosure is achieved by a process for the manufacture of a donor substrate for the transfer of a piezoelectric layer onto a support substrate comprising the stages of providing a handling substrate, in particular, a silicon-based substrate, providing a piezoelectric substrate, depositing a polymer layer on a free face of the piezoelectric substrate, assembling the piezoelectric substrate on the handling substrate in such a way that the polymer layer is positioned sandwiched between the piezoelectric substrate and the handling substrate, wherein a stage of surface activation treatment of the surface of the piezoelectric substrate coming into contact with the polymer layer is carried out before the stage of assembling the piezoelectric substrate on the handling substrate.

A surface treatment is a mechanical, chemical, electrochemical or physical treatment, the aim of which is to modify the appearance or the function of the surface of materials in order to adapt them to a given use. A surface treatment makes possible the functionalization, the activation or the cleaning of the surface, or a combination of these effects. Thus, the stage of surface treatment of the piezoelectric substrate in the process according to the present disclosure makes it possible to modify the appearance or the function of the surface of the piezoelectric substrate in order to adapt it to contact with the polymer layer, in order to obtain a better interface between the piezoelectric material and the polymer layer. Thus, the process according to the present disclosure makes it possible to obtain a donor substrate having an improved mechanical stability with respect to the state of the art.

According to one embodiment, during the stage of deposition of a polymer layer on the piezoelectric substrate, the polymer layer can be deposited directly on the treated surface of the piezoelectric substrate. The treated surface of the piezoelectric substrate makes it possible to offer an improved adhesion to the polymer layer, which will be deposited on top. Thus, the polymer layer alone makes it possible to produce good adhesion of the piezoelectric substrate to another layer or another substrate. A polymer layer can be deposited, for example, by a centrifugal deposition process directly on the piezoelectric substrate.

The subject matter of the present disclosure is also achieved by a process for the manufacture of a donor substrate for the transfer of a piezoelectric layer onto a support substrate comprising the stages of providing a handling substrate, in particular, a silicon-based substrate, providing a piezoelectric substrate, depositing a polymer layer on a free face of the handling substrate, assembling the piezoelectric substrate on the handling substrate in such a way that the polymer layer is positioned sandwiched between the piezoelectric substrate and the handling substrate, characterized in that a stage of activation treatment of the surface of the piezoelectric substrate coming into contact with the polymer layer of the handling substrate during the assembling stage is carried out before the stage of assembling the piezoelectric substrate on the handling substrate.

Likewise, the stage of surface treatment of the piezoelectric substrate in the process according to the present disclosure makes it possible to modify the appearance or the function of the surface of the piezoelectric substrate in order to adapt it to contact with the polymer layer of the handling substrate, in order to obtain a better interface between the piezoelectric material and the polymer layer. Thus, the process according to the present disclosure makes it possible to obtain a donor substrate having an improved mechanical stability with respect to the state of the art.

According to one embodiment, during the stage of deposition of a polymer layer on the handling substrate, the polymer layer can be positioned directly on the handling substrate. The polymer layer alone makes it possible to produce good adhesion to another layer or another substrate. A polymer layer can be deposited, for example, by a centrifugal deposition process directly on the handling substrate.

According to one embodiment, the assembling stage of the process for the manufacture of a donor substrate can comprise a stage of treatment of the polymer layer in order to obtain a crosslinked polymer layer in order to bond the handling substrate to the piezoelectric substrate. The formation of a crosslinked polymer layer by a stage of treatment of the polymer layer is simple to carry out and not very expensive.

According to one embodiment, the stage of surface activation treatment can be an oxygen-based surface activation treatment creating pendant bonds on the surface of the piezoelectric substrate coming into contact with the polymer layer. The oxygen-based surface activation treatment consists of an oxidation of the surface of a material. The oxidation of the surface molecules makes it possible to increase the surface tension of a support. The oxygen-based surface activation treatment makes possible the creation of free radicals at the surface, which promote the adhesion of a thin layer in contact with these free radicals.

According to one embodiment, the stage of surface activation treatment of the piezoelectric substrate can be a treatment with ozone, in particular, by the wet route or assisted by UV. A treatment with ozone is a treatment, which makes it possible to modify the surface of the piezoelectric substrate in order to improve the interface between the polymer layer and the surface of the piezoelectric substrate.

According to one embodiment, the stage of surface activation treatment of the piezoelectric substrate can be a treatment with a solution based on hydrogen peroxide. A treatment with a solution based on hydrogen peroxide makes it possible to modify the surface of the piezoelectric substrate in order to improve the interface between the polymer layer and the surface of the piezoelectric substrate.

According to one embodiment, the stage of surface activation treatment of the piezoelectric substrate can be a plasma treatment, in particular, an oxygen-based plasma treatment. The plasma surface treatment is a treatment by the dry route, which makes it possible to improve the chemical characteristics of the material for better adhesion to a coating layer. Thus, the plasma treatment stage of the process according to the present disclosure makes it possible to improve the adhesion between the polymer layer and the surface of the piezoelectric substrate of the donor substrate, and results in an improved mechanical stability of the donor substrate with respect to the state of the art.

According to one embodiment, the piezoelectric substrate can be a lithium (LTO), lithium niobate (LNO), aluminum nitride (AlN), lead zirconate titanate (PZT), langasite or langatate substrate. The process according to the present disclosure can be used for these materials, which play a major role in devices making use of the piezoelectric effect.

According to one embodiment, a stage of thinning the piezoelectric substrate of the donor substrate can be carried out after the assembling stage, in particular, after the stage of treatment of the polymer layer of the assembling stage, so as to obtain either a thinned piezoelectric substrate with a thickness t, which is less than the thickness t₁ of the piezoelectric substrate, or a piezoelectric layer with a thickness t₂, which is less than the thickness t₁ of the piezoelectric substrate. Thus, starting from a thick piezoelectric substrate, a thinner piezoelectric substrate or a piezoelectric layer of a desired thickness is obtained and the donor substrate manufactured according to the process of the present disclosure can be used as donor substrate for the transfer of a thin piezoelectric layer onto a support substrate in order to obtain a piezoelectric-on-insulator (POI) substrate.

In a process for the manufacture of a POI substrate, the piezoelectric material and the material of the support substrate exhibiting very different thermal expansion coefficients, a significant deformation of the assembly occurs. In such a process, by virtue of the use of a donor substrate, the thick piezoelectric substrate is held between the handling substrate and the support substrate. The choice of the materials and of the thicknesses of the handling substrate and of the support substrate makes it possible to ensure a certain symmetry of the thermal expansion coefficients, and thus to minimize the deformation of the assembly during the application of heat treatments during the process for the manufacture of a piezoelectric-on-insulator (POI) substrate.

The subject matter of the present disclosure can also be achieved by a process for transfer of a piezoelectric layer onto a support substrate comprising stages of providing a donor substrate obtained by the manufacturing process described above, forming a weakened zone inside the piezoelectric substrate, providing a support substrate, in particular, a silicon-based substrate, attaching the donor substrate to the support substrate in order to obtain a support substrate-donor substrate assembly, and carrying out fracturing along the weakened zone in order to separate a piezoelectric layer from the remainder of the donor substrate. In a process for the manufacture of a POI substrate, the piezoelectric material and the material of the support substrate exhibiting very different thermal expansion coefficients, a significant deformation of the assembly occurs. In such a process, by virtue of the use of a donor substrate, the thick piezoelectric substrate is held between the handling substrate and the support substrate. The choice of the materials and of the thicknesses of the handling substrate and of the support substrate makes it possible to ensure a certain symmetry of the thermal expansion coefficients, and thus to minimize the deformation of the assembly during the application of heat treatments during the process for the manufacture of a piezoelectric-on-insulator (POI) substrate.

### BRIEF DESCRIPTION OF THE DRAWINGS

The present disclosure and its advantages will be explained in more detail subsequently by means of preferred embodiments and with the support, in particular, of the following accompanying figures, in which the reference numbers identify characteristics of the present disclosure.

FIG. 1 diagrammatically represents a process for the manufacture of a donor substrate according to a first embodiment of the present disclosure.

FIG. 2 diagrammatically represents a process for the manufacture of a donor substrate according to an alternative form of the first embodiment of the present disclosure.

FIG. 3 diagrammatically represents a process for the manufacture of a donor substrate according to a second embodiment of the present disclosure.

FIG. 4 diagrammatically represents a process for the transfer of a piezoelectric layer according to a third embodiment of the present disclosure.

### DETAILED DESCRIPTION

The present disclosure will be described in more detail using advantageous embodiments in an exemplary way and with reference to the drawings. The embodiments described are simply possible configurations and it should be kept in mind that the individual characteristics as described above can be provided independently of one another or can be omitted entirely during the implementation of the present disclosure.

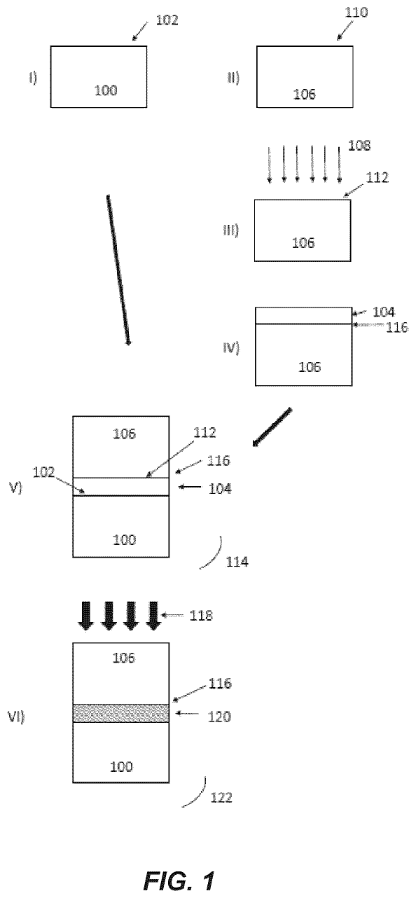

FIG. 1 diagrammatically illustrates a process for the manufacture of a donor substrate used for the transfer of a piezoelectric layer of the donor substrate onto a support substrate according to a first embodiment of the present disclosure.

The process for the manufacture of a donor substrate begins with stage I) of providing a handling substrate 100, in particular, a bulk substrate. A bulk substrate is a substrate based on just one material typically with a thickness of between 300 μm and 800 μm. The handling substrate 100 is made of a material, the thermal expansion coefficient of which is close to that of the material of the support substrate onto which the piezoelectric layer is intended to be transferred. The term “close” is understood to mean a difference in thermal expansion coefficient between the material of the handling substrate 100 and the material of the support substrate of less than or equal to 5% and preferably equal to or in the vicinity of 0%. The handling substrate 100 can be a substrate based on silicon, on sapphire, on aluminum nitride (AlN), on silicon carbide (SiC) or also on gallium arsenide (GaAs). The handling substrate 100 can be a crystalline or polycrystalline substrate.

During stage II) of the process according to the first embodiment, a piezoelectric substrate 106 is provided. It is preferably a bulk substrate of piezoelectric material, the thickness of which is typically of the order of at least 300 μm, preferably of at least 350 μm. According to an alternative form, the substrate of piezoelectric material 106 can also be a thick layer of piezoelectric material with a thickness of between 25 μm and 50 μm, deposited on another substrate.

The piezoelectric material can, for example, be lithium tantalate (LTO), lithium niobate (LNO), aluminum nitride (AlN), lead zirconate titanate (PZT), langasite or langatate.

The piezoelectric substrate 106 can first be subjected to one or more stages of cleaning, brushing or polishing its free surface 110 in order to remove particles or dust and thus to obtain a free surface 110, which is clean and of good quality in order to subsequently carry out a successive layer deposition.

According to the present disclosure, the piezoelectric substrate 106 is subsequently subjected to a stage III) of surface activation treatment 108 on one of its free faces 110 in order to obtain an activated surface 112.

The surface activation treatment 108 of the free surface 110 of the piezoelectric substrate 106 is a treatment that makes possible the activation of the surface to be treated. Such a surface activation treatment 108 makes it possible to prepare the surface of a material for contact with a successive layer, either during a successive deposition or during an operation of bringing into contact with another substrate. For this, the surface activation treatment 108 modifies the properties of the surface. A surface activation treatment can be mechanical, chemical, electrochemical or physical.

The surface activation treatment 108 can be an oxygen-based surface activation treatment. The oxidation of the surface molecules makes it possible to increase the surface tension of a support creating pendant bonds on the surface. The oxygen-based surface activation treatment 108 makes possible the creation of free radicals at the surface, which promote the adhesion of a thin layer in contact with these free radicals. Thus, the activated surface 112 of the piezoelectric substrate 106 comprises pendant bonds. These pendant bonds represent bonding sites that make it possible to obtain better bonding with the surface of a material brought into contact with the pendant bonds. This is because the pendant bonds of the activated surface 112 of the piezoelectric substrate 106 will produce covalent bonds with the pendant bonds of the surface of the material brought into contact with the activated surface 112 of the piezoelectric substrate 106.

According to one embodiment, the stage III) of surface activation treatment 108 of the piezoelectric substrate 106 can be a treatment with ozone, in particular, by the wet route or assisted by UV. The presence of ozone makes it possible to oxidize the surface molecules. The use of irradiation by UV makes it possible to create free radicals.

According to another embodiment, the stage III) of surface activation treatment 108 of the piezoelectric substrate 106 can be a treatment with a solution based on hydrogen peroxide. The treatment with hydrogen peroxide is also known as active oxygen treatment and makes possible the formation of free radicals by oxidation.

According to another embodiment, the stage III) of surface activation treatment 108 of the piezoelectric substrate 106 can be a plasma treatment, in particular, an oxygen-based plasma treatment. A plasma treatment is a treatment by the dry route that makes possible the activation of the surface. The plasma surface treatment consists of a very strong oxidation of the surface of a material.

Thus, the surface activation treatment 108 of the process according to the present disclosure makes it possible to improve the chemical characteristics of the activated surface 112 of the piezoelectric substrate 106 by creating bonding sites for better adhesion to a layer, which is deposited or brought into contact with the activated surface 112 of the piezoelectric substrate 106 a posteriori in the process.

A stage IV) of deposition of a polymer layer 104 on the activated surface 112 of the piezoelectric substrate 106 is subsequently carried out.

The deposition of the polymer layer 104 is advantageously carried out by spin coating. This technique consists in spinning round and round at a given speed the substrate on which the deposition of the polymer layer is intended to take place, in order to spread the polymer layer 104 uniformly over the entire free surface 112 of the piezoelectric substrate 106 by centrifugal force. To this end, the piezoelectric substrate 106 is typically placed and held by applying vacuum on a rotary plate. The thickness of the polymer layer 104 obtained depends on the parameters used during the deposition of the layer, that is to say, for example, on the speed and duration of rotation of the substrate and on the volume of the polymer solution deposited on the activated surface 112 of the piezoelectric substrate 106. The thickness of the polymer layer 104 is typically of between 1 μm and 6 μm, preferably of the order of 3.5 μm.

The polymer layer 104 can be a photopolymerizable layer based on thiol-ene resin. For example, the layer sold under the reference “NOA 61” by Norland Products can be used in the present disclosure as polymer layer 104.

During the stage of deposition of the polymer layer 104, the polymer layer 104 is deposited directly in contact with the activated surface 112 of the piezoelectric substrate 106.

The free surface 110 of the piezoelectric substrate 106 was subjected beforehand to the stage of surface activation treatment 108 for activation of the free surface 110 and thus in order to obtain good adhesion of the polymer layer 104 to the free surface 110 of the piezoelectric substrate 106.

Thus, the pendant bonds present on the activated surface 112 of the piezoelectric substrate 106 create bonding sites promoting the adhesion of the polymer layer 104 formed on the activated surface 112 of the piezoelectric substrate 106. The pendant bonds present on the activated surface 112 of the piezoelectric substrate 106 will form covalent bonds with the pendant bonds of the polymer layer 104. Thus, the contact interface 116 between the piezoelectric substrate 106 and the polymer layer 104 is consolidated/reinforced.

After the deposition by spin coating of the polymer layer 104 on the piezoelectric substrate 106, a heat treatment can be carried out to improve the adhesion of the polymer layer 104 to the activated surface 112 of the piezoelectric substrate 106 at the contact interface 116.

The piezoelectric substrate 106 obtained after stage IV) is subsequently assembled with the handling substrate 100 provided in stage I) during an assembling stage V) in order to obtain a donor substrate 114.

The assembling of the piezoelectric substrate 106 on the handling substrate 100 is carried out such that the polymer layer 104 is positioned sandwiched between the piezoelectric substrate 106 and the handling substrate 100.

The contact interface 116 between the piezoelectric substrate 106 and the polymer layer 104 is consolidated/reinforced and results in an improved mechanical stability of the donor substrate 114 with respect to the state of the art.

Once the two substrates are assembled, a bonding stage VI) is carried out in order to bond the piezoelectric substrate 106 to the handling substrate 100 in order to form a stable donor substrate 122.

The polymer layer 104 is subjected to a treatment for crosslinking the polymer layer 104 in order to modify the mechanical properties of the polymer layer 104. Crosslinking is the general term denoting the process of formation of covalent bonds or of relatively short sequences of chemical bonds in order to join two polymer chains. When the polymer chains are crosslinked, the polymer layer 104 becomes stiffer. Covalent chemical crosslinkings are stable mechanically and thermally, so that, once formed, they are difficult to break.

A crosslinking treatment can be carried out by use of heat, of pressure, by a change in pH or by irradiation. According to the present disclosure, the crosslinking treatment can be carried out by irradiation by a light flux 118 of the polymer layer 104. The irradiation is carried out through the piezoelectric substrate 106 or the handling substrate 100 in order to crosslink the polymer layer 104 and to obtain a crosslinked polymer layer 120, also called polymerized layer 120.

The irradiation of the donor substrate 114 is carried out using a light source, preferably a laser. The light radiation 118, or light flux, is preferably ultraviolet radiation (UV), preferably with a wavelength of between 320 nm and 365 nm.

The thickness of the crosslinked polymer layer 120 is preferably of between 1 μm and 6.5 μm, in particular, approximately 3.5 μm. This thickness depends, in particular, on the material of the polymer layer 104 deposited before bonding, on the thickness of the polymer layer and on the irradiation conditions.

The crosslinking of the polymer layer 104 by UV irradiation 118 makes it possible to release radicals, which will trigger the polymerization of the polymer layer 104. The polymerization of the polymer layer 104 results in chemical bonds that are mechanically and thermally stable, so that, once formed, they are difficult to break. Thus, the linking between the pendant bonds of the activated surface 112 of the piezoelectric substrate 106 and the crosslinked polymer layer 120 results in a mechanically and thermally stable link.

The polymerized layer 120 thus ensures the mechanical cohesion of the donor substrate 122, by keeping the handling substrate 100 and the piezoelectric substrate 106, which form the donor substrate 122, bonded together.

By virtue of the surface activation treatment 108, the contact interface 116 between the crosslinked polymer layer 120 and the piezoelectric substrate 106 exhibits an improvement in the adhesion between the polymer layer 120 and the surface of the piezoelectric substrate 106; the donor substrate 122 thus obtained by the manufacturing process according to the present disclosure exhibits an improved mechanical stability at the polymer-piezoelectric interface.

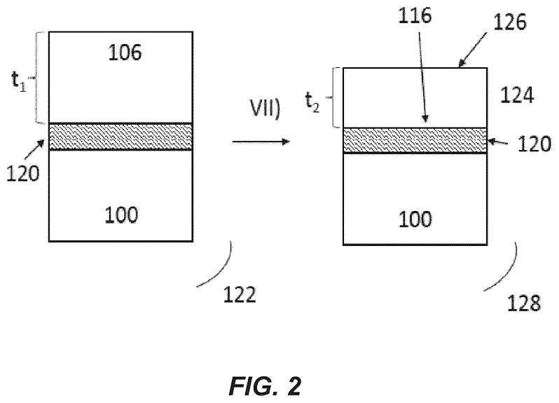

FIG. 2 diagrammatically represents a process for the manufacture of a donor substrate for the transfer of a piezoelectric layer onto a support substrate according to an alternative form of the first embodiment of the present disclosure. None of the characteristics in common with the first embodiment and using the same reference number as above will be described again but reference is made to their detailed description above.

The process according to the first embodiment comprises, after stage VI) illustrated in FIG. 1, a stage of thinning VII) the piezoelectric substrate 106 of the donor substrate 122 obtained according to the process of the first embodiment.

This thinning stage VII) can be carried out by a process of grinding or else by a process of chemical etching of the piezoelectric substrate 106 in order to reduce the thickness t₁ of the substrate of piezoelectric material 106 of the donor substrate 122 in order to obtain either a thinned piezoelectric substrate 106 with a thickness t of less than t₁, or a piezoelectric layer 124 with a thickness t₂ of the order of 20 μm, or also between 5 μm and 25 μm.

A treatment of the free surface 126 of the piezoelectric layer 124 obtained can also be carried out once the thinning stage VII) is complete in order to improve the quality of the free surface 126 of the piezoelectric layer 124.

Given the mechanical stability of the donor substrate 122 obtained by the process according to the first embodiment, the stages of thinning and of treatment to which the donor substrate 122 is subjected can be carried out without the polymer-piezoelectric interface 116 being affected by these mechanical and/or thermal stages and the risk of debonding at this contact interface 116 is reduced, in particular, eliminated. Thus, the donor substrate 128 shows a mechanical stability, which allows it to be used upstream in a process for transfer of piezoelectric layer 124 onto a support substrate 140.

A donor substrate 128 is thus obtained with a crosslinked polymer layer 120 positioned between a handling substrate 100 and a piezoelectric layer 124, the handling substrate 100 being in contact with the crosslinked polymer layer 120 of the piezoelectric layer 124.

The assembly of the handling substrate 100 either with the piezoelectric substrate 106 or, after thinning of the latter as described in the preceding section, with the piezoelectric layer 124, according to the embodiments described, can be advantageous not only as donor substrate 122, 128, but can constitute a substrate, per se, which can be used for the manufacture of acoustic components.

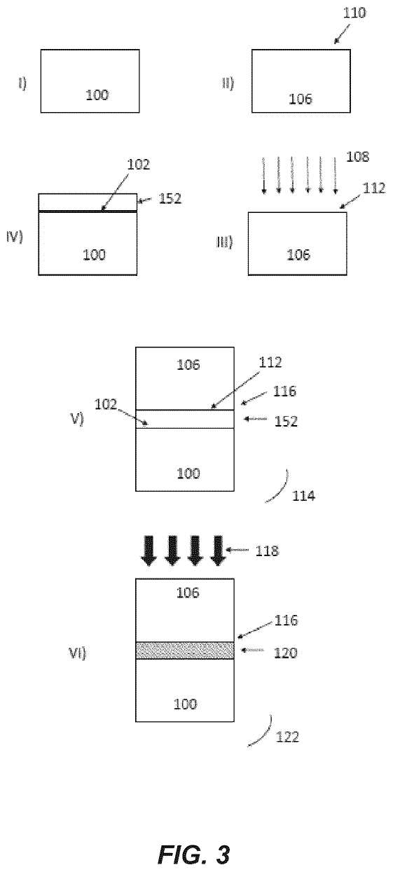

FIG. 3 shows the second embodiment of the present disclosure in which the stage of deposition IV) of the polymer layer 152 is different with respect to the first embodiment. The stage of deposition of the polymer layer 152 is carried out on the handling substrate 100. All the other stages I), II), III) and V) to VII) are the same as in the first embodiment and its alternative form. None of the characteristics in common with the first embodiment and using the same reference number as above will be described again but reference is made to their detailed description above.

During the stage of deposition IV) of the polymer layer, the polymer layer 152 is deposited directly in contact with the free surface 102 of the handling substrate 100. The handling substrate 100 can first be subjected to one or more stages of cleaning, brushing or polishing its free surface 102 in order to remove particles or dust and thus to obtain a free surface 102, which is clean and of good quality in order to subsequently carry out the deposition of the polymer layer 152.

During the assembling stage V), the polymer layer 152 of the handling substrate 100 is brought into direct contact with the activated surface 112 of the piezoelectric substrate 106. Thus, the contact interface 116 between the polymer layer 152 and the activated surface 112 of the piezoelectric substrate 106 also exhibits better adhesion. This is because, in the same way as described above, the pendant bonds present on the activated surface 112 of the piezoelectric substrate 106 create bonding sites promoting the adhesion of the polymer layer 152 formed on the handling substrate 100 with the activated surface 112 of the piezoelectric substrate 106. Thus, the contact interface 116 between the piezoelectric substrate 106 and the polymer layer 152 is consolidated/reinforced and results in an improved mechanical stability of the donor substrate 114 with respect to the state of the art.

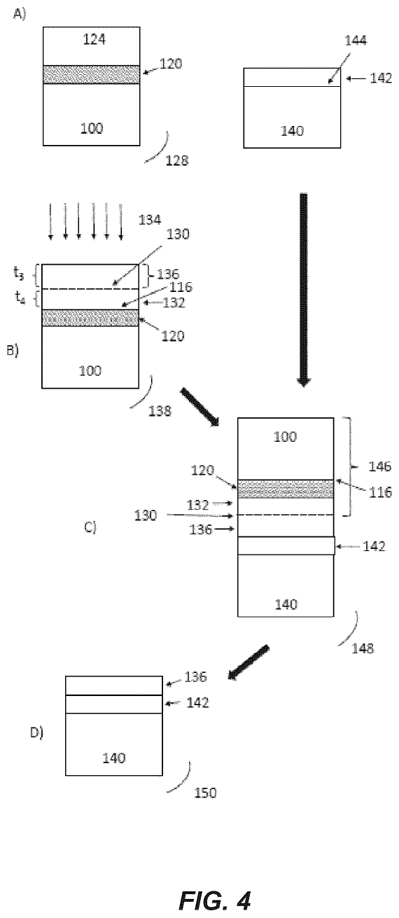

FIG. 4 diagrammatically represents a process for the transfer of a piezoelectric layer according to a third embodiment of the present disclosure.

The process for transfer of a piezoelectric layer onto a support substrate according to the present disclosure comprises the stage of providing a donor substrate obtained by the implementation of the process for the manufacture of a donor substrate described with respect to FIGS. 1 to 3 according to the first embodiment of the present disclosure and its alternative form and according to the second embodiment of the present disclosure and its alternative form.

During stage A), the donor substrate 128 and the support substrate 140 are provided.

The support substrate 140 can be a bulk substrate based on silicon, on sapphire, on aluminum nitride (AlN), on silicon carbide (SiC) or also on gallium arsenide (GaAs). The support substrate 140 can be a crystalline or polycrystalline substrate.

As illustrated in FIG. 4, the support substrate 140 can comprise a dielectric layer 142 previously deposited on the free surface 144 of the support substrate 140 by deposition by spin coating or by a deposition technique, such as plasma deposition or evaporation deposition. A heat treatment can also be carried out after the deposition of the dielectric layer 142 in order to optimize the adhesion of this dielectric layer 142 to the support substrate 140, or also a surface treatment in order to improve the quality of the surface of the dielectric layer 142 deposited.

In an alternative form, the support substrate 140 can comprise a layer of natural oxide, which is formed on the free surface 144 of the support substrate 140.

The dielectric layer 142 is, for example, a layer of silicon dioxide. However, the dielectric layer 142 can also be a layer of nitride, or a layer comprising a combination of nitride and of oxide, or a superimposition of a layer of oxide and of a layer of nitride. For example, in the case of a support substrate made of silicon, it will be possible to form a layer of oxide, or a layer of silicon nitride Si₃N₄, a layer comprising a combination of nitride and of oxide SiOₓN_{y}, or a superimposition of a layer of oxide and of a layer of silicon nitride Si₃N₄.

In an alternative form, the support substrate 140 can also comprise other layers. For example, layers for producing a Bragg mirror or a trapping layer can be present on the support substrate 140. In particular, a trapping layer of polycrystalline, amorphous or porous silicon type can be present, with a thickness varying between 500 nm and 5 μm.

In an alternative form, the support substrate 140 is provided without a dielectric layer 142 and/or without a layer of natural oxide.

In an alternative form, a dielectric layer can be provided on the piezoelectric layer 136 of the donor substrate 138 instead of being provided on the support substrate 140.

In another alternative form, a dielectric layer can be provided on both substrates, the donor substrate 128 and the support substrate 140.

A stage B) of forming a weakened zone 130 in the piezoelectric layer 124 of the donor substrate 128 is carried out so as to delimit the piezoelectric layer 136 to be transferred onto the support substrate 140.

This stage of formation of a weakened zone 130 is carried out by an implantation 134 of atomic or ionic entities in the piezoelectric layer 124 of the donor substrate 128. The atomic or ionic implantation 134 is carried out in such a way that the weakened zone 130 is located inside the piezoelectric layer 124 and separates a piezoelectric layer 136 from the remainder 132 of the piezoelectric layer 124. The atomic or ionic entities are implanted at a predetermined depth of the piezoelectric layer 124, which determines the thickness t₃ of the piezoelectric layer 136 to be transferred and the thickness t₄ of the remainder 132 of the piezoelectric layer 124. The thickness t₃ is typically between 50 nm and 1 μm, in particular, of the order of 600 nm.

The donor substrate 138 obtained comprises a weakened zone 130 separating the piezoelectric layer 136 to be transferred from the remainder 132 of the piezoelectric layer 124.

Stage C) of the process of transfer according to the present disclosure comprises assembling the donor substrate 138 with the support substrate 140 in order to obtain a support substrate-donor substrate assembly, which forms the heterostructure 148. The assembling of the donor substrate 138 with the support substrate 140 takes place at the level of the dielectric layer 142, in such a way that the piezoelectric layer 136 of the donor substrate 138 is in contact with the dielectric layer 142 of the support substrate 140.

In the alternative form where the support substrate 140 does not comprise a dielectric layer 142, the assembling takes place in such a way that the piezoelectric layer 136 of the donor substrate 148 is in direct contact with the free surface 144 of the support substrate 140. The assembling takes place by molecular adhesion between the two substrates, at the piezoelectric-support substrate interface.

In an alternative form, the assembling of the donor substrate 138 with the support substrate 140 takes place between the dielectric layer 142 and a dielectric layer formed on the donor substrate 148, as mentioned above. This dielectric layer is, for example, a layer of silicon oxide, a layer of silicon nitride Si₃N₄ or a layer comprising a combination of silicon nitride and oxide, also known as silicon oxynitride, SiOₓN_{y}, or a superimposition of a layer of oxide and of a layer of nitride. According to an alternative form, the formation of this dielectric layer can be followed by a heat treatment in order to improve the adhesion of the dielectric layer to the piezoelectric layer 124. A surface treatment for improving the quality of the surface of this dielectric layer can also be carried out, in particular, after the stage of implantation 134 and before stage C) mentioned above.

Subsequently, a stage D) of producing a fracture along the weakened zone 130 of the donor substrate 148 in order to separate the piezoelectric layer 136 from the remainder 146 of the donor substrate 148 is carried out. This fracturing stage can be carried out thermally or mechanically. During a thermal separation, the temperature used is equal to or less than 300° C.

The use of the donor substrate 128 manufactured according to the present disclosure makes it possible to prevent debonding between the piezoelectric layer 124 and the polymer layer 120 of the donor substrate 128 during the fracturing of the donor substrate 128, by virtue of the contact interface 116 between the polymer layer 120 and the piezoelectric layer 124 comprising a better mechanical stability. This makes it possible to obtain an actual fracture of the donor substrate 148 at the weakened zone 130 in order to obtain a POI substrate 150.

The POI substrate 150 illustrated in stage D) of FIG. 4 is produced by the process of transfer of a piezoelectric layer according to the present disclosure and comprises a support substrate 140, a dielectric layer 142 and a piezoelectric layer 136.

The embodiments described are simply possible configurations and it should be kept in mind that the individual characteristics of the different embodiments can be combined with one another or provided independently of one another.

1. A method of manufacturing a donor substrate for the transfer of a piezoelectric layer onto a support substrate, comprising:
providing a handling substrate;
providing a piezoelectric substrate;
performing a surface activation treatment on a surface of the piezoelectric substrate to form an activated surface of the piezoelectric substrate;
depositing a polymer layer onto at least one of the activated surface of the piezoelectric substrate or a surface of the handling substrate; and
assembling the piezoelectric substrate on the handling substrate such that the polymer layer is between the activated surface of the piezoelectric substrate and the handling substrate.

2. The method of claim 1, wherein depositing the polymer layer onto at least one of the activated surface of the piezoelectric substrate or a surface of the handling substrate comprises depositing the polymer layer directly on the activated surface of the piezoelectric substrate.

3. (canceled)

4. The method of claim 1, wherein depositing the polymer layer onto at least one of the activated surface of the piezoelectric substrate or a surface of the handling substrate comprises depositing the polymer layer directly on the handling substrate.

5. The method of claim 1, further comprising treating the polymer layer to obtain a crosslinked polymer layer and bond the handling substrate to the piezoelectric substrate.

6. The method of claim 1, wherein performing the surface activation treatment on the surface of the piezoelectric substrate to form the activated surface of the piezoelectric substrate comprises performing an oxygen-based surface activation treatment creating pendant bonds on the activated surface of the piezoelectric substrate.

7. The method of claim 1, wherein performing the surface activation treatment on the surface of the piezoelectric substrate to form the activated surface of the piezoelectric substrate comprises performing a treatment with ozone.

8. The method of claim 1, wherein performing the surface activation treatment on the surface of the piezoelectric substrate to form the activated surface of the piezoelectric substrate comprises performing a treatment with a solution based on hydrogen peroxide.

9. The method of claim 1, wherein performing the surface activation treatment on the surface of the piezoelectric substrate to form the activated surface of the piezoelectric substrate comprises performing a plasma treatment.

10. The method of claim 1, wherein providing the piezoelectric substrate comprises selecting the piezoelectric substrate to be a lithium tantalate substrate, a lithium niobate substrate, an aluminum nitride substrate, a lead zirconate titanate substrate, a langasite substrate, or a langatate substrate.

11. The method of claim 1, further comprising thinning the piezoelectric substrate of the donor substrate after assembling the piezoelectric substrate on the handling substrate.

12. A method of transferring a piezoelectric layer onto a support substrate, comprising:
providing a donor substrate by performing a method according to claim 1;
forming a weakened zone within the piezoelectric substrate of the donor substrate;
providing a support substrate;
attaching the donor substrate to the support substrate to obtain a support substrate-donor substrate assembly; and
producing a fracture along the weakened zone to separate a piezoelectric layer from a remainder of the donor substrate.

13. The method of claim 1, further comprising selecting the handling substrate to comprise a silicon-based substrate.

14. The method of claim 7, wherein performing the treatment with ozone comprises performing a wet treatment.

15. The method of claim 7, wherein performing the treatment with ozone comprises performing a UV assisted treatment.

16. The method of claim 9, wherein performing the plasma treatment comprises performing an oxygen-based plasma treatment.

17. The method of claim 11, wherein thinning the piezoelectric substrate of the donor substrate comprises grinding the piezoelectric substrate.
